(19) United States
(12) Patent Application Publication
(10) Pub. No.: US 2018/0287347 A1
(43) Pub. Date: Oct. 4, 2018

(54) OPTICAL SEMICONDUCTOR DEVICE

(71) Applicant: SUMITOMO ELECTRIC INDUSTRIES, LTD., Osaka (JP)

(72) Inventor: Jun-ichi HASHIMOTO, Yokohama-shi (JP)

(73) Assignee: SUMITOMO ELECTRIC INDUSTRIES, LTD., Osaka (JP)

(21) Appl. No.: 15/918,480

(22) Filed: Mar. 12, 2018

(30) Foreign Application Priority Data
Mar. 30, 2017 (JP) 2017-068158

(51) Int. Cl. H01S 5/34; H01S 5/022; H01S 5/042

(52) U.S. Cl. CPC H01S 5/3401; H01S 5/0425; H01S 5/02276; H01S 5/02296

(57) ABSTRACT

An optical semiconductor device capable of reducing the influence of reflected light is disclosed. The optical semiconductor device includes: a base; an optical semiconductor element that is provided on the upper surface of the base and emits light from a front end face and a rear end face, the rear end face facing the base; a cap that is provided on the base and has an emission window in a position facing the front end face of the optical semiconductor element, the light passing through the emission window; and a first optical absorption film that is provided in a region on the upper surface of the base and absorbs the light, the region facing the rear end face of the optical semiconductor element.

### CROSS-REFERENCE TO RELATED APPLICATION

This application is based upon and claims the benefit of priority of the prior Japanese Patent Application No. 2017-068158, filed on Mar. 30, 2017, the entire contents of which are incorporated herein by reference.

### BACKGROUND

### (i) Technical Field

The present invention relates to an optical semiconductor device.

### (ii) Related Art

A conventional optical semiconductor device has a light emitting element included in a housing (see Japanese Patent Application Laid-Open No. 5-175614, for example). Light emitted from the front end face of the light emitting element is output to the outside of the housing, and light emitted from the rear end face of the light emitting element enters a light receiving element.

### SUMMARY

However, part of the light emitted from the rear end face is reflected and then travels toward the front side. This might deform the shape of the light emitted from the front end face. As a result, the light collecting properties of the emitted light might be degraded, the accuracy of measurement of the power of the emitted light might become lower, and the accuracy of sensing that uses light might also become lower, for example.

Therefore, the present invention aims to provide an optical semiconductor device capable of reducing the influence of reflected light.

According to an aspect of the present invention, there is provided an optical semiconductor device, including: a base; an optical semiconductor element that is provided on an upper surface of the base and emits light from a front end face and a rear end face, the rear end face facing the base; a cap that is provided on the base and has an emission window in a position facing the front end face of the optical semiconductor element, the light passing through the emission window; and a first optical absorption film that is provided in a region on the upper surface of the base and absorbs the light, the region facing the rear end face of the optical semiconductor element.

### BRIEF DESCRIPTION OF THE DRAWINGS

FIG. 1 is a perspective view of an optical semiconductor device according to a first embodiment;

FIG. 2 is a perspective view of the optical semiconductor device;

FIG. 3 is a cross-sectional view of the optical semiconductor device;

FIG. 4A is a perspective diagram illustrating a method of manufacturing the optical semiconductor device;

FIG. 4B is a cross-sectional diagram illustrating the method of manufacturing the optical semiconductor device;

FIG. 5 is a cross-sectional view of an optical semiconductor device according to a comparative example;

FIGS. 6A and 6B are graphs showing examples of optical absorptances of the first optical absorption film;

FIG. 7 is a cross-sectional view of an optical semiconductor device according to a second embodiment;

FIG. 8 is a cross-sectional view of an optical semiconductor device according to a third embodiment;

FIG. 9 is a cross-sectional diagram illustrating a method of manufacturing the optical semiconductor device;

FIG. 10 is a cross-sectional view of an optical semiconductor device according to a fourth embodiment;

FIG. 11 is a cross-sectional view of an optical semiconductor device according to a fifth embodiment;

FIG. 12 is a cross-sectional view of an optical semiconductor device according to a sixth embodiment; and

FIGS. 13A and 13B are perspective views of an optical semiconductor device according to a seventh embodiment.

### DETAILED DESCRIPTION

### DESCRIPTION OF EMBODIMENTS OF THE PRESENT INVENTION

First, the contents of embodiments of the present invention are listed below.

An embodiment of the present invention is 1) an optical semiconductor device that includes: a base; an optical semiconductor element that is provided on the upper surface of the base and emits light from the front end face and the rear end face, the rear end face facing the base; a cap that is provided on the base and has an emission window in a position facing the front end face of the optical semiconductor element, the light passing through the emission window; and a first optical absorption film that is provided in a region on the upper surface of the base and absorbs the light, the region facing the rear end face of the optical semiconductor element. The first optical absorption film absorbs the emitted light from the rear end face of the optical semiconductor element. Thus, the intensity of reflected light becomes lower, and the influence of the reflected light on the emitted light from the front end face of the optical semiconductor element can be reduced.

2) The optical semiconductor element may be a quantum cascade laser. The quantum cascade laser outputs light of longer wavelengths than any wavelength in an optical communication wavelength range, such as mid-infrared light. The first optical absorption film absorbs such light, and thus, the influence of reflected light can be reduced.

3) The first optical absorption film may be a silicon oxide film, a silicon oxynitride film, a silicon nitride film, an alumina film, a benzocyclobutene film, or a polyimide film. As the first optical absorption film has a high optical absorptance, the influence of reflected light can be effectively reduced.

4) The thickness of the first optical absorption film may be not smaller than 0.2 μm and not greater than 5 μm. As the first optical absorption film has a high optical absorptance and is not too thick, degradation of the heat release properties of the optical semiconductor device can be prevented.

5) The wavelength of the light to be emitted from the optical semiconductor element maybe not smaller than 7 μm and not greater than 30 μm. As the first optical absorption film has a high optical absorptance for light of such a wavelength, the influence of reflected light can be effectively reduced.

6) The thickness of the region of the first optical absorption film facing the optical semiconductor element may be greater than the thickness of a region other than the region of the first optical absorption film facing the optical semiconductor element. The optical absorptance of the first optical absorption film becomes higher as the first optical absorption film becomes thicker. Thus, the influence of reflected light can be effectively reduced. Also, the heat release properties improve at the portion where the first optical absorption film is thin.

7) The cap may have a sidewall surrounding the optical semiconductor element, and the optical semiconductor device may further include a second optical absorption film that is provided on the sidewall and absorbs the light. As the first optical absorption film and the second optical absorption film absorb light, the influence of reflected light can be effectively reduced.

8) The cap may have an upper inner wall facing the optical semiconductor element, and the optical semiconductor device may further include a third optical absorption film that is provided on the upper inner wall and absorbs the light. As the first optical absorption film, the second optical absorption film, and the third optical absorption film absorb light, the influence of reflected light can be effectively reduced.

9) The optical semiconductor device may have a can-type package or an HHL package. With this arrangement, the influence of reflected light on emitted light from the package can be reduced.

### DETAILED DESCRIPTION OF EMBODIMENTS OF THE PRESENT INVENTION

The following is a description of specific examples of optical semiconductor devices according to embodiments of the present invention, with reference to the accompanying drawings. It should be noted that the present invention is not limited to these examples but is shown by the claims, and it is intended that all modifications are included in the equivalents of the claims and the scope of the claims.

### First Embodiment

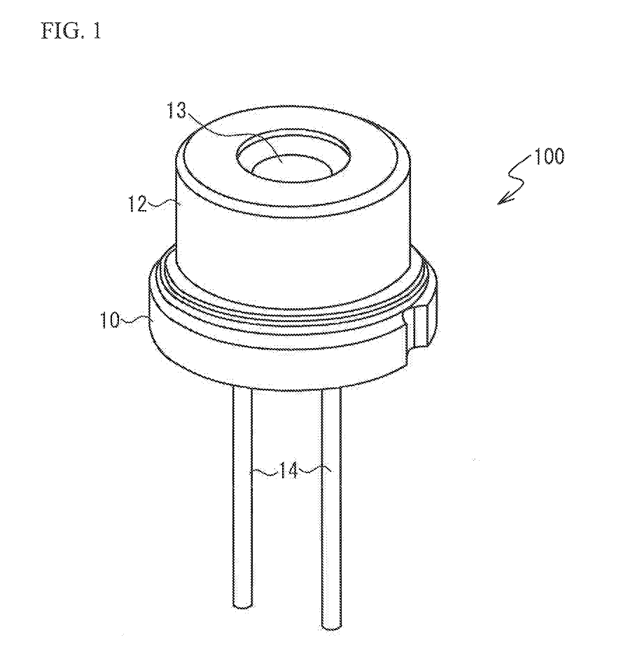

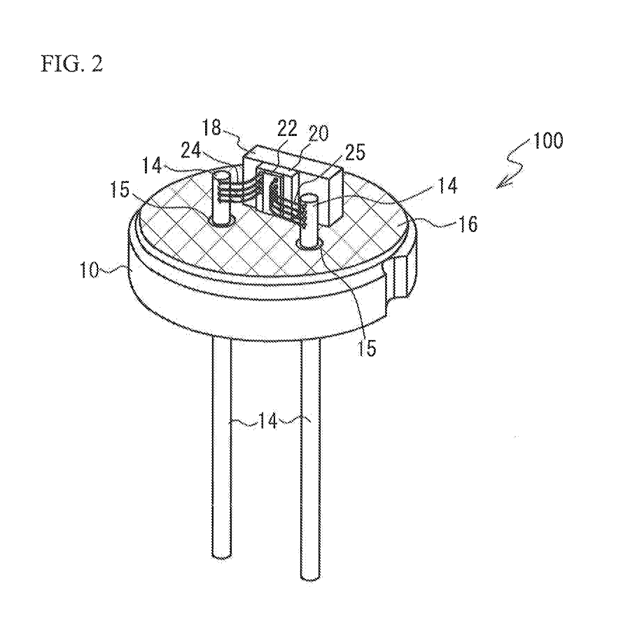

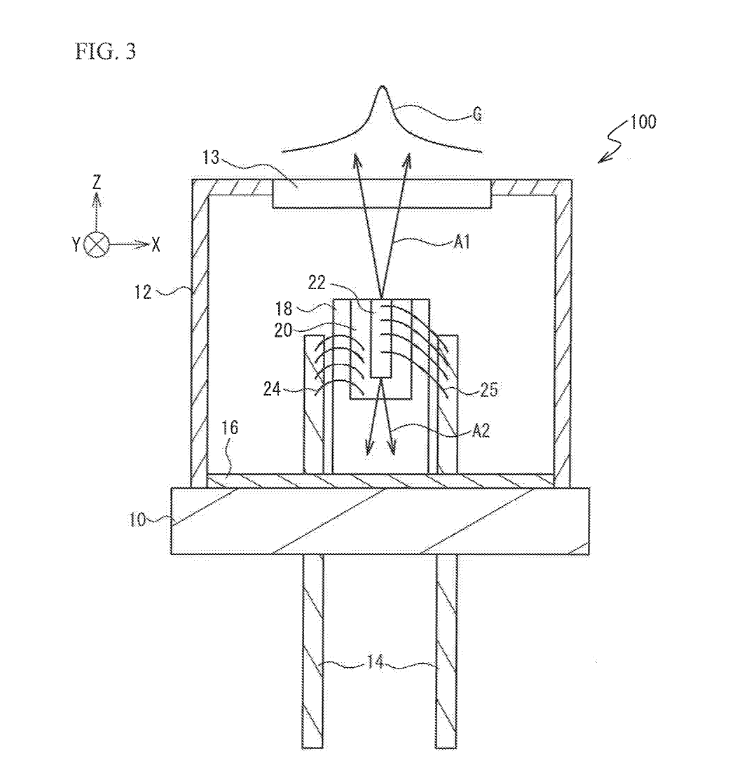

FIG. 1 is a perspective view of an optical semiconductor device 100 according to a first embodiment. FIG. 2 is a perspective view of the optical semiconductor device 100, with a cap 12 removed. FIG. 3 is a cross-sectional view of the optical semiconductor device 100.

### Optical Semiconductor Device

As shown in FIG. 1 through 3, the optical semiconductor device 100 is designed as a can-type package. As shown in FIG. 1, the optical semiconductor device 100 includes a base 10 and a cap 12. As the cap 12 is attached onto the base 10 having a cylindrical shape, the later described optical semiconductor element 22 and other components are hermetically sealed. Two leads 14 extend from the bottom surface of the base 10. The base 10, the cap 12, and the leads 14 are made of metal. The diameter of the base 10 is 5.6 mm, for example.

As shown in FIG. 2, a first optical absorption film 16, a mount block 18, a sub mount 20, and the optical semiconductor element 22 are provided on the upper surface of the base 10. The first optical absorption film 16 covers almost the entire upper surface of the base 10, and is made of a dielectric material, such as silicon oxide (SiO₂), silicon nitride (SiN), silicon oxynitride (SiON), alumina (Al₂O₃), benzocyclobutene, or polyimide. The base 10 does not have the first optical absorption film 16 formed on its surface in contact with the cap 12. The first optical absorption film 16 has a uniform thickness, which is not smaller than 0.2 μm and not greater than 5 μm, for example. The mount block 18 is made of metal, and the sub mount 20 is made of metal or ceramic. The sub mount 20 is mounted on one surface of the mount block 18, and the optical semiconductor element 22 is bonded to one surface of the sub mount 20 by die-bonding.

As shown in FIGS. 2 and 3, the leads 14 penetrate through the base 10, and protrude upward and downward from the base 10. Shields 15 are provided between the leads 14 and the base 10, and surround the leads 14. The shields 15 are made of glass, for example, and are designed to achieve airtight sealing and insulate the leads 14 from the base 10. One of the two leads 14 is electrically connected to the sub mount 20 by bonding wires 24, and has a reference potential. The other one of the two leads 14 is electrically connected to the optical semiconductor element 22 by bonding wires 25. This lead 14 is used to supply power to the optical semiconductor element 22. The bonding wires 24 and 25 are made of gold (Au), for example, and consist of four bonding wires 24 and four bonding wires 25, for example. To supply a large current to the optical semiconductor element 22, it is preferable to use multiple bonding wires 24 and multiple bonding wires 25.

The optical semiconductor element 22 is a quantum cascade laser (QCL) chip, for example. The width of the optical semiconductor element 22 is 400 to 800 μm, for example, and the cavity length is 1000 to 3000 μm, for example. As voltage of 10 to 15 V and power of 1 to 10 W are supplied from the leads 14 to the optical semiconductor element 22, the optical semiconductor element 22 emits light of longer wavelengths than any wavelength in the communication wavelength range (1.3 to 1.6 μm in wavelength), for example. The wavelength of emitted light falls within the mid-infrared range, or more particularly, within the range of 7 to 30 μm. As indicated by arrows in FIG. 3, emitted light A1 is output from the front end face (the face on the +Z side in FIG. 3), and emitted light A2 is output from the rear end face (the face on the −Z side in FIG. 3). The Z-axis is the optical axis of the optical semiconductor element 22.

The emitted light A1 and the emitted light A2 spread in the X-Y plane. The X-direction in FIG. 3 is a horizontal transverse direction of light, and the Y-direction is a perpendicular transverse direction of light. The spread angle (full angle at half maximum) in the horizontal transverse direction is 40 degrees, for example, and the spread angle (full angle at half maximum) in the perpendicular transverse direction is 50 degrees, for example. According to a far field pattern (FFP) of the emitted light A1, the distribution of the intensity of the emitted light in the X-Z plane has a Gaussian curve as indicated by a curved line G in FIG. 3. In a plane (the X-Y plane in FIG. 3) perpendicular to the optical axis of the optical semiconductor element 22, on the other hand, the intensity distribution has an elliptical shape. The front end face is not provided with a low-reflectivity coating, and the rear end face is not provided with a high-reflectivity coating. Because of this, the power of the emitted light A1 from the front end face is substantially the same as that of the emitted light A2 from the rear end face, and is 2 to 50 mW, for example.

As shown in FIGS. 1 and 3, an emission window 13 made of a semiconductor such as zinc selenide (ZnSe) is formed at a portion of the cap 12 facing the optical semiconductor element 22. The emitted light A1 from the front end face of the optical semiconductor element 22 passes through the emission window 13. That is, light can be output from the can-type package to the outside through the emission window 13.

Meanwhile, the emitted light A2 from the rear end face of the optical semiconductor element 22 travels toward the base 10. The first optical absorption film 16 provided on the upper surface of the base 10 absorbs the emitted light A2. Accordingly, the intensity of the reflected light generated when the emitted light A2 is reflected becomes lower. As a result, the influence of the emitted light A2 from the rear end face on the emitted light A1 from the front end face is reduced. This aspect will be described later in detail.

### Manufacturing Method

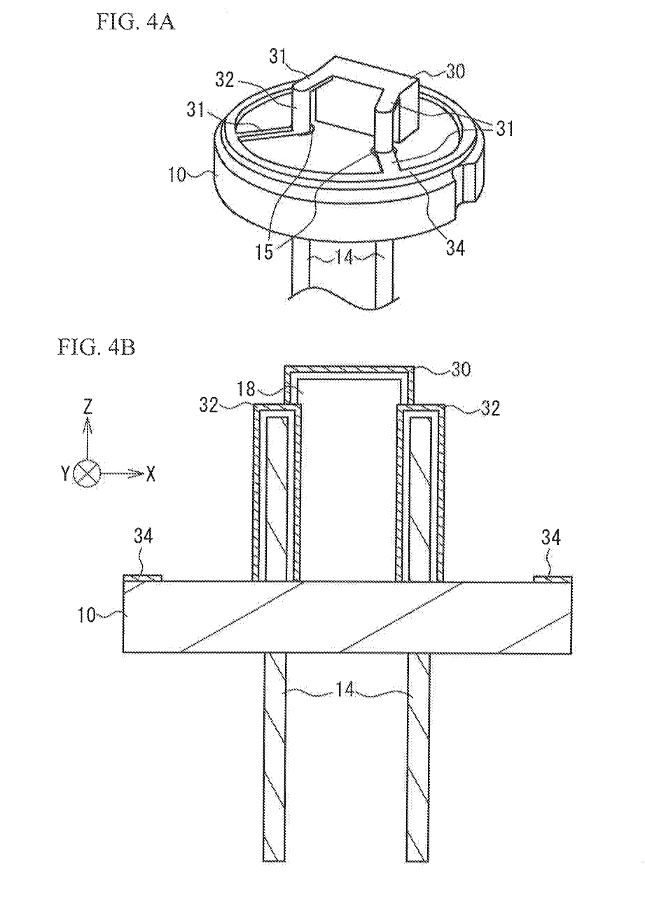

FIG. 4A is a perspective diagram illustrating a method of manufacturing the optical semiconductor device 100. FIG. 4B is a cross-sectional diagram illustrating the method of manufacturing the optical semiconductor device 100. As shown in FIGS. 4A and 4B, the mount block 18 is mounted on the base 10. After that, caps 30, 32, and 34 that are 50 to 100 μm in thickness and are made of aluminum (Al), for example, are attached onto the base 10. The cap 30 covers the mount block 18, the caps 32 cover the portions of the leads 14 protruding upward from the base 10, and the cap 34 covers the outer circumferential portion of the upper surface of the base 10. That is, the caps 30, 32, and 34 cover the portions on which the first optical absorption film 16 is not to be provided. The distance between the inner wall of the cap 30 and the mount block 18, and the distance between the inner wall of each cap 32 and each corresponding lead 14 are 100 μm, for example. These caps are joined to one another by joining portions 31. Although the first optical absorption film 16 is not to be formed under the joining portions 31, it is preferable to provide the first optical absorption film 16 in a wide area, to reduce the reflected light. Therefore, the joining portions 31 are preferably made as narrow as possible.

After the caps 30, 32, and 34 are attached, the base 10 together with other bases 10 are put into a film forming device (such as a sputtering device or a CVD device), for example. By a sputtering technique or a chemical vapor deposition (CVD) technique, the first optical absorption film 16 is formed on the portions exposed between the caps 30, 32, and 34. The caps 30, 32, and 34 are then removed, and the sub mount 20 is bonded onto the mount block 18 by die-bonding, and the optical semiconductor element 22 is bonded onto the sub mount 20 by die-bonding. Further, one of the leads 14 is electrically connected to the sub mount 20 by wire-bonding, and the other one of the leads 14 is electrically connected to the optical semiconductor element 22 by wire-bonding. The cap 12 is then fixed to the region of the base 10 on which the first optical absorption film 16 is not formed to hermetically seal the optical semiconductor element 22 and other components on the base 10. Through the above process, the optical semiconductor device 100 is formed.

Alternatively, another process may be adopted as described below. Before the mount block 18 and the leads 14 are provided, the outer circumferential portion of the base 10 and the portion on which the mount block 18 is to be mounted are covered with caps. After that, the first optical absorption film 16 is formed. After the film formation, the caps are removed, the mount block 18 is mounted on the base 10, and the leads 14 are inserted into the base 10. The steps thereafter are the same as those described above.

### COMPARATIVE EXAMPLE

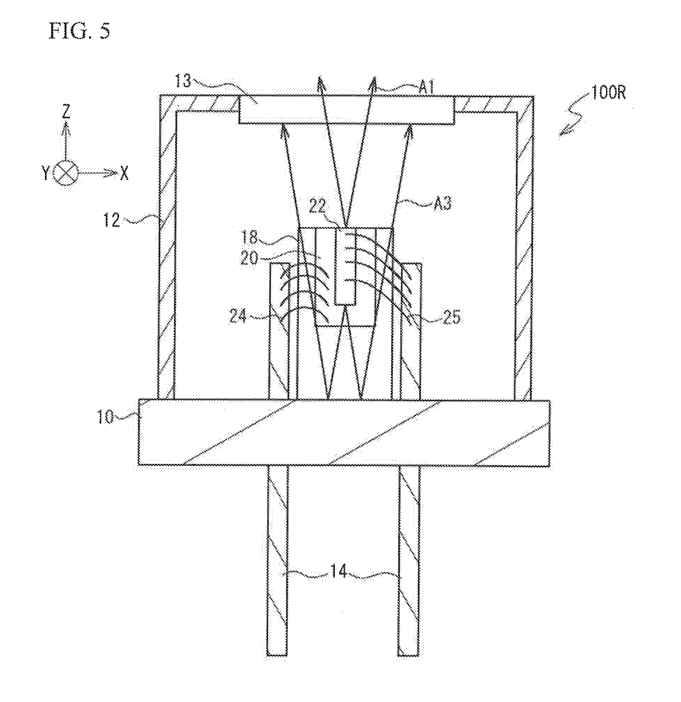

FIG. 5 is a cross-sectional view of an optical semiconductor device 100R according to a comparative example. The optical semiconductor device 100R does not include the first optical absorption film 16. The other components are the same as those of the optical semiconductor device 100. In this comparative example, light emitted from the rear end face is reflected by the upper surface of the base 10. Reflected light A3 indicated by arrows in FIG. 5 travels upward from the upper surface of the base 10, and is emitted through the emission window 13. The reflected light A3 mixes with the emitted light A1 (indicated by arrows) from the front end face at a rate of 20 to 30%, for example. As a result, the FFP shape of the emitted beam from the emission window 13 is deformed, and the Gaussian distribution is disturbed. Consequently, the light collecting properties of the emitted beam are degraded, and the accuracy of measurement of the emission power becomes lower. Furthermore, the emitted light A1 and the reflected light A3 have different phases. Therefore, the reflected light A3 becomes noise to the emitted light A1, and lowers the accuracy of sensing that uses light.

In the first embodiment, on the other hand, the first optical absorption film 16 is provided on the base 10 in a region facing the rear end face of the optical semiconductor element 22, as shown in FIGS. 2 and 3. As the first optical absorption film 16 absorbs the emitted light A2 from the rear end face, the intensity of the reflected light becomes lower. Accordingly, the influence of the reflected light on the emitted light A1 from the front end face can be reduced. Thus, deterioration of the beam shape of the emitted light A1 output from the can-type package can be prevented, and the output beam can maintain a Gaussian shape, for example, as shown in FIG. 3. The light collecting properties of the emitted light A1 improve, and the accuracy of power measurement becomes higher. Further, the reflected light to turn into noise is reduced. Thus, the accuracy of sensing using the emitted light A1 becomes higher.

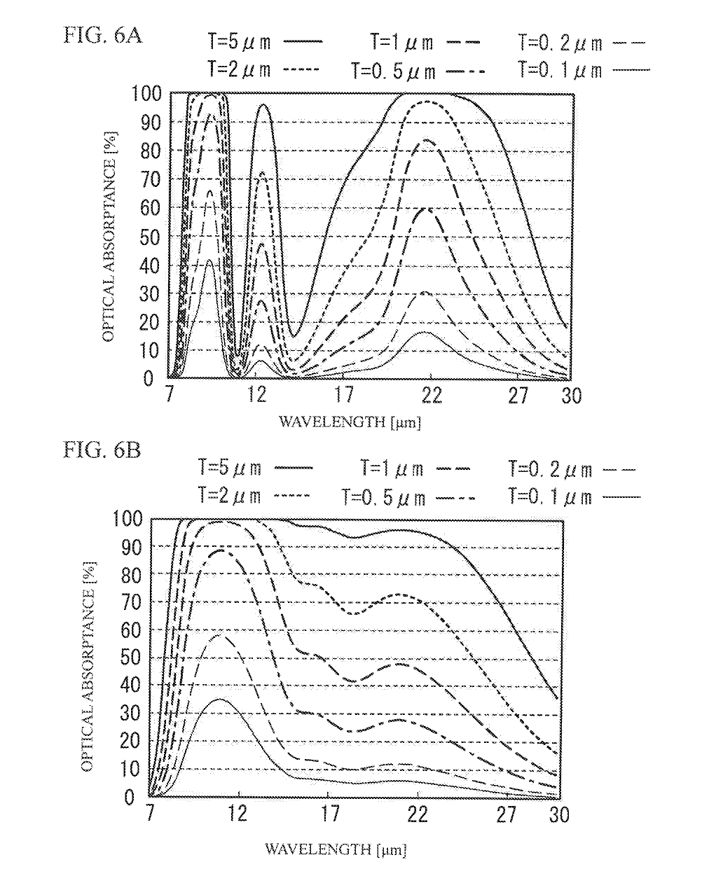

FIGS. 6A and 6B are graphs showing examples of the optical absorptance of the first optical absorption film 16. An optical absorptance is a value expressed in percentage (%), and indicates the proportion of the emitted light A2 absorbed by the first optical absorption film 16 when returning to the emission window 13 after being reflected by the upper surface of the base 10. FIG. 6A shows an example where a SiO₂ film is used as the first optical absorption film 16. FIG. 6B shows an example where a SiN film is used as the first optical absorption film 16. In each graph, the abscissa axis indicates light wavelength, and the ordinate axis indicates the optical absorptance of the first optical absorption film 16. T represents the thickness of the first optical absorption film 16.

As shown in FIG. 6A, where a SiO₂ film is used as the first optical absorption film 16, high optical absorptances are obtained in the regions of 8 to 10 μm, 11 to 13 μm, and 20 to 25 μm in wavelength. To reduce the influence of reflected light, the optical absorptance is preferably 50% or higher, for example. Therefore, in a case where the optical semiconductor element 22 emits light of 9 μm in wavelength, for example, the thickness T of the first optical absorption film 16 is preferably at least 0.2 μm. In a case where the optical semiconductor element 22 emits light of 22 μm in wavelength, the thickness T of the first optical absorption film 16 is preferably at least 0.5 μm. The optical absorptance becomes higher as the first optical absorption film 16 becomes thicker. Where the thickness T is 5 μm, the light absorptances are 50% or higher in the regions of 8 to 10 μm, 11 to 13 82 m, and 20 to 25 μm in wavelength.

As shown in FIG. 6B, where a SiN film is used as the first optical absorption film 16, high optical absorptances are obtained in a wide region of 8 to 30 μm in wavelength. To achieve an optical absorptance of 50% or higher in a case where the optical semiconductor element 22 emits light of 9 to 15 μm in wavelength, the thickness T of the first optical absorption film 16 is preferably at least 1 μm. In a case where the optical semiconductor element 22 emits light of 8 to 26 μm in wavelength, the thickness T of the first optical absorption film 16 is preferably at least 2 μm.

As shown in FIGS. 6A and 6B, the optical absorptance becomes higher as the first optical absorption film 16 becomes thicker. However, if the first optical absorption film 16 is thick, the efficiency of heat release through the base 10 becomes lower. To prevent such deterioration of the heat release properties, the thickness T of the first optical absorption film 16 is preferably 5 μm or smaller, for example. The thickness T may be 0.3 μm or greater, 0.5 μm or greater, 4 μm or smaller, or 6 μm or smaller, for example.

The first optical absorption film 16 may not be made of SiO₂ or SiN, but may be made of a dielectric material such as silicon oxynitride (SiON), alumina (Al₂O₃), benzocyclobutene, or polyimide, for example. In accordance with the wavelength of emitted light, a dielectric material having a high optical absorptance at the wavelength can be used. The optical semiconductor element 22 is a quantum cascade laser, for example, and emits light of longer wavelengths (7 to 30 μm, for example) than any wavelength in the communication wavelength range. As the first optical absorption film 16 that absorbs light of such wavelengths is used, the influence of reflected light can be reduced.

The first optical absorption film 16 is provided on the upper surface of the base 10 at least in the region facing the rear end face of the optical semiconductor element 22. To effectively reduce the influence of reflected light, the first optical absorption film 16 preferably covers the region in which the emitted light A2 spreads, and, more preferably, covers the upper surface of the base 10 except for the outer circumferential portion thereof, for example.

### Second Embodiment

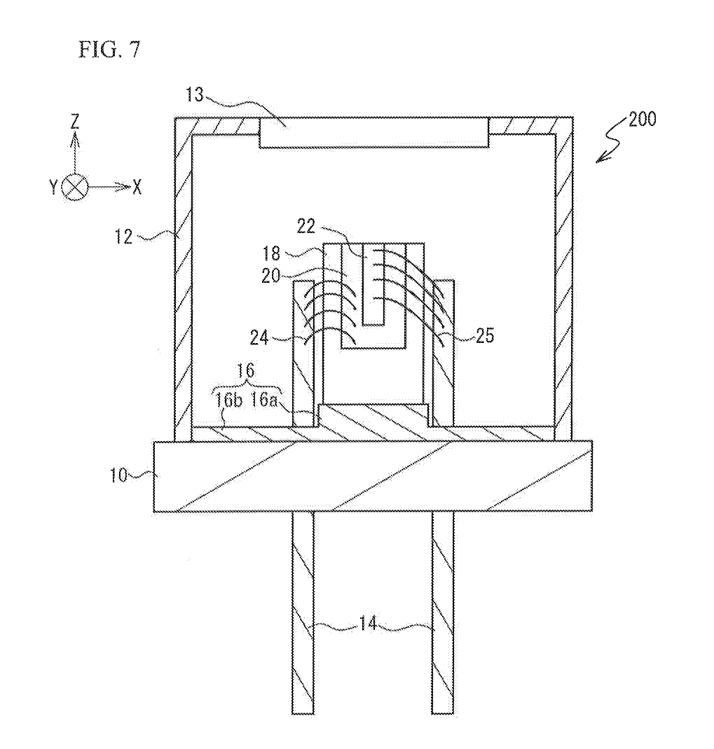

FIG. 7 is a cross-sectional view of an optical semiconductor device 200 according to a second embodiment. Explanation of the same components as those of the first embodiment is not made herein. As shown in FIG. 7, of the first optical absorption film 16, a region 16a facing the optical semiconductor element 22 is thick, and the other region 16b is thin. The thickness of the region 16a is 2 μm, for example, and the thickness of the region 16b is 0.1 μm, for example.

### Manufacturing Method

Through the process described above with reference to FIGS. 4A and 4B, for example, a dielectric film of a uniform thickness is formed. After that, a cap that has an opening at the portion to face the optical semiconductor element 22 near the mount block 18 and covers the other portion is provided, and the same dielectric film as above is formed. As a result, the first optical absorption film 16 having the thick region 16a and the thin region 16b is formed. Alternatively, after a dielectric film of 2 μm in thickness is formed, the portion to face the optical semiconductor element 22 may be protected with a cover, and etching may be selectively performed on the other portion. The first optical absorption film 16 may be formed in such a manner.

In the second embodiment, the first optical absorption film 16 absorbs the emitted light from the rear end face as in the first embodiment. Thus, the influence of reflected light can be reduced. The intensity of the emitted light from the optical semiconductor element 22 conforms to a Gaussian distribution, for example. Accordingly, the emitted light from the optical semiconductor element 22 is strong at the center, and becomes gradually weaker toward the outside. Thus, the region 16a of the first optical absorption film 16 facing the rear end face of the optical semiconductor element 22 is irradiated with the strong emitted light from the rear end face. Since the region 16a is thicker than the region 16b, the optical absorptance of the region 16a is higher than that of the region 16b. Thus, the emitted light from the rear end face of the optical semiconductor element 22 can be efficiently absorbed, and the influence of reflected light can be effectively reduced.

Meanwhile, the region 16b of the first optical absorption film 16 is thinner than the region 16a. Therefore, the heat release properties of the portion of the optical semiconductor device 200 corresponding to the region 16b are better than the portion corresponding to the region 16a, and heat generated in the optical semiconductor element 22 is effectively released through the base 10. To achieve both a high optical absorptance and excellent heat release properties, the thickness of the region 16a is 1 μm or greater, 2 μm or greater, or 5 μm or smaller, for example. The thickness of the region 16b is not smaller than 0.2 μm and not greater than 0.5 μm, for example.

### Third Embodiment

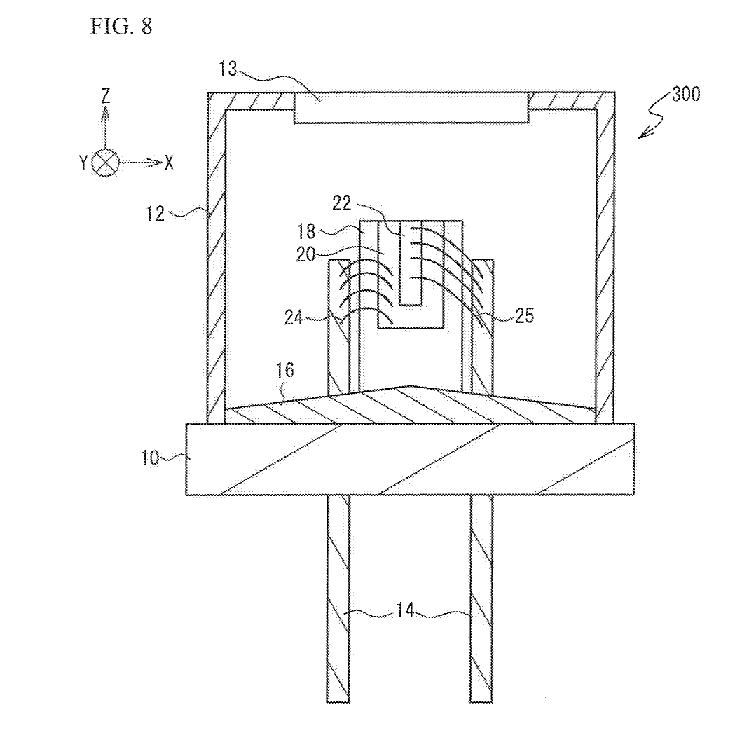

FIG. 8 is a cross-sectional view of an optical semiconductor device 300 according to a third embodiment. Explanation of the same components as those of the first embodiment is not made herein. As shown in FIG. 8, the first optical absorption film 16 becomes gradually thinner in the direction from the region facing the rear end face of the optical semiconductor element 22 toward the outer circumferential portion of the base 10.

### Manufacturing Method

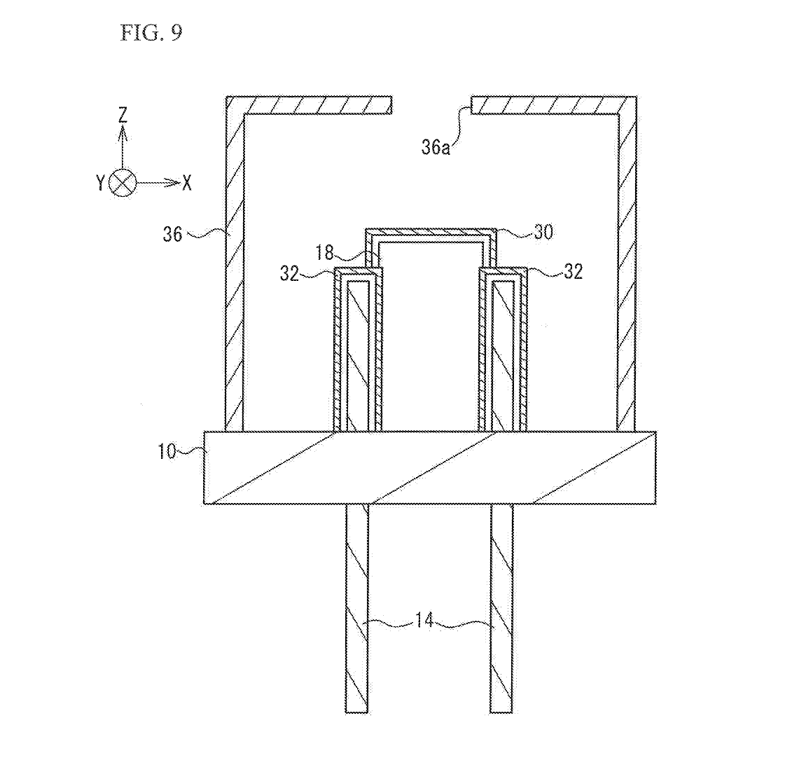

FIG. 9 is a cross-sectional diagram illustrating a method of manufacturing the optical semiconductor device 300. As shown in FIG. 9, after the leads 14 and the mount block 18 are attached to the base 10, a cap 36 is provided. An opening 36a penetrating through the cap 36 is formed in an upper portion of the cap 36. The opening 36a is located at the center of the upper surface of the cap 36, and faces the central portion of the upper surface of the base 10. After the cap 36 is provided, the first optical absorption film 16 is formed by a sputtering technique or a CVD technique, for example. Accordingly, the film formation rate is high at the central portion of the base 10, and is low at the outer circumferential portion. Thus, the sloped first optical absorption film 16 is formed.

In the third embodiment, the first optical absorption film 16 absorbs the emitted light from the rear end face as in the first embodiment. Thus, the influence of reflected light can be reduced. The intensity of the emitted light from the optical semiconductor element 22 conforms to a Gaussian distribution, for example. Accordingly, the emitted light from the optical semiconductor element 22 is strong at the center, and becomes gradually weaker toward the outside. The first optical absorption film 16 becomes gradually thinner from the center toward the outside. That is, of the first optical absorption film 16, the region facing the rear end face of the optical semiconductor element 22 is thicker than the other region, and has a higher optical absorptance accordingly. Thus, the first optical absorption film 16 can efficiently absorb the emitted light from the rear end face of the optical semiconductor element 22, and effectively reduce the influence of reflected light. Furthermore, as the first optical absorption film 16 is thinner at the outer circumferential portion, better heat release properties are achieved.

### Fourth Embodiment

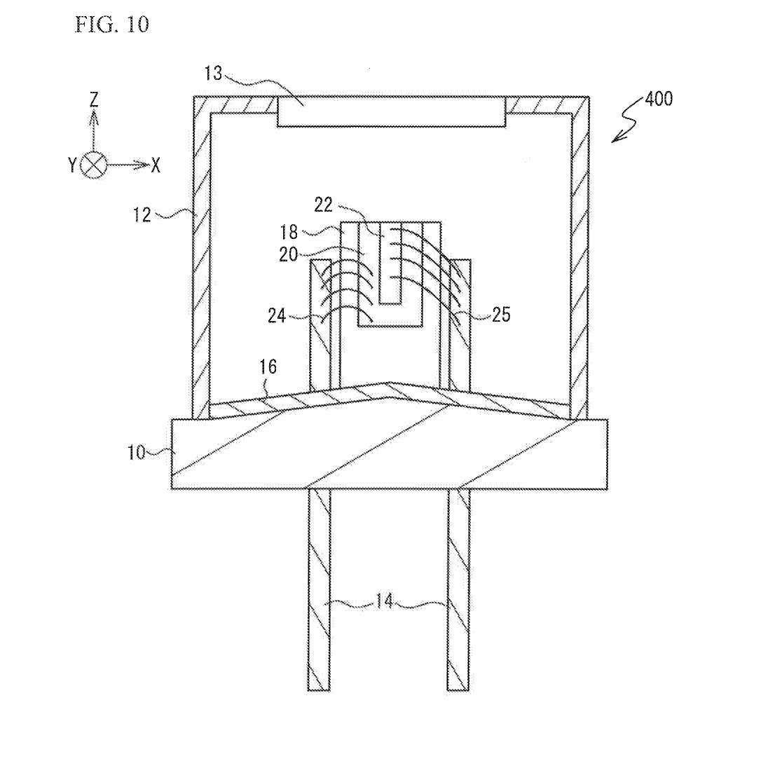

FIG. 10 is a cross-sectional view of an optical semiconductor device 400 according to a fourth embodiment. Explanation of the same components as those of the first embodiment is not made herein. As shown in FIG. 10, the upper surface of the base 10 is sloped from the central portion toward the outer circumferential portion, and the central portion is higher than the outer circumferential portion. The first optical absorption film 16 is formed on the sloped upper surface of the base 10.

In the fourth embodiment, the first optical absorption film 16 absorbs the emitted light from the rear end face as in the first embodiment. Thus, the influence of reflected light can be reduced. Furthermore, as the upper surface of the base 10 is sloped, a large proportion of the emitted light from the rear end face of the optical semiconductor element 22 is reflected toward the outer sides of the emission window 13 of the cap 12. Because of this, the reflected light does not easily reach the emission window 13, and thus, the influence of the reflected light on the emitted light from the front end face can be reduced.

### Fifth Embodiment

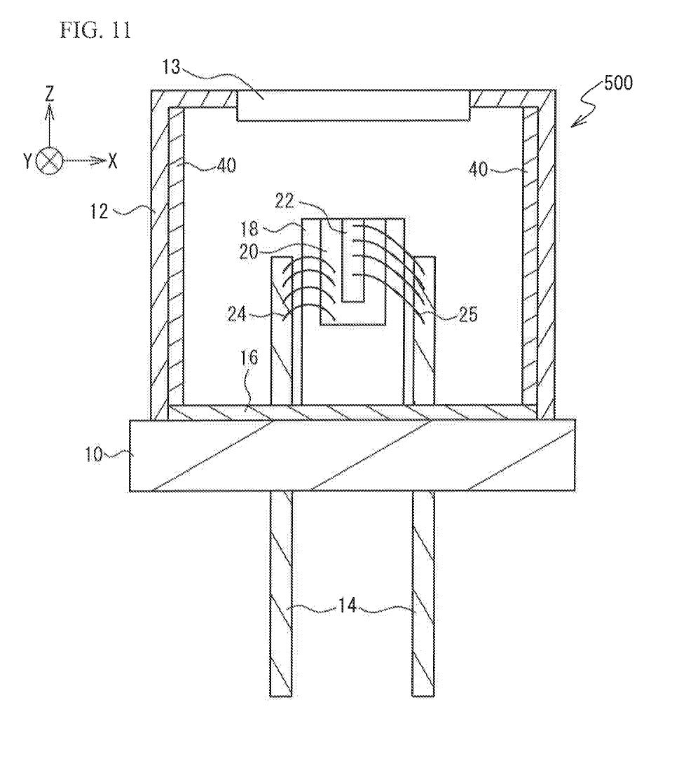

FIG. 11 is a cross-sectional view of an optical semiconductor device 500 according to a fifth embodiment. Explanation of the same components as those of the first embodiment is not made herein. As shown in FIG. 11, a second optical absorption film 40 is formed on the inner sidewalls of the cap 12. The first optical absorption film 16 and the second optical absorption film 40 are made of a dielectric material, such as SiO₂, SiN, SiON, Al₂O₃, benzocyclobutene, or polyimide. The thickness of each of the optical absorption films is not smaller than 0.2 μm and not greater than 5 μm, for example.

### Manufacturing Method

By a sputtering method, a CVD method, or the like, the second optical absorption film 40 is formed on the inner sidewalls of the cap 12 prior to attachment to the base 10. Covers are provided on the outer surface and the upper inner wall of the cap 12, so that the second optical absorption film 40 can be formed only on the inner sidewalls.

In the fifth embodiment, the first optical absorption film 16 absorbs the emitted light from the rear end face, and the second optical absorption film 40 absorbs reflected light. Thus, the influence of the reflected light on the emitted light from the front end face can be reduced. As shown in FIGS. 6A and 6B, the first optical absorption film 16 has an optical absorptance of 50% or higher, for example. The second optical absorption film 40 further absorbs light after the first optical absorption film 16 absorbs light. Thus, the intensity of the light from the rear end face of the optical semiconductor element 22 can be effectively lowered.

### Sixth Embodiment

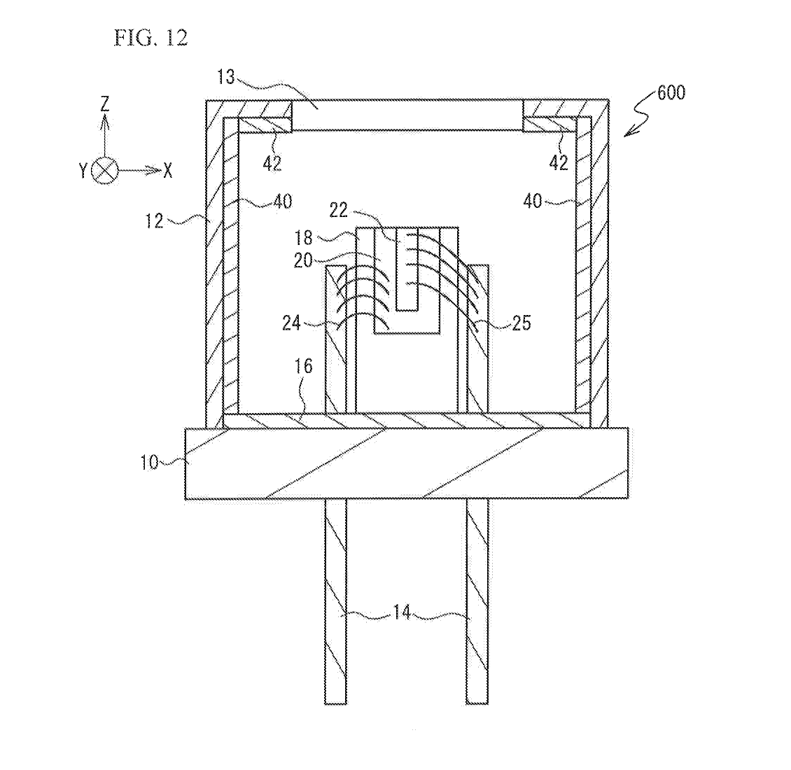

FIG. 12 is a cross-sectional view of an optical semiconductor device 600 according to a sixth embodiment. Explanation of the same components as those of the first and fifth embodiments is not made herein. As shown in FIG. 12, the second optical absorption film 40 is formed on the inner sidewalls of the cap 12, and a third optical absorption film 42 is formed on the upper inner wall of the cap 12. The first optical absorption film 16, the second optical absorption film 40, and the third optical absorption film 42 are made of a dielectric material, such as SiO₂, SiN, SiON, Al₂O₃, benzocyclobutene, or polyimide. The thickness of each of the optical absorption films is not smaller than 0.2 μm and not greater than 5 μm, for example.

In the sixth embodiment, the first optical absorption film 16 absorbs the emitted light from the rear end face, and the second optical absorption film 40 and the third optical absorption film 42 absorb reflected light. Thus, the influence of the reflected light on the emitted light from the front end face can be reduced. As the second optical absorption film 40 and the third optical absorption film 42 cover the entire inner walls of the cap 12, the reflected light can be effectively absorbed. In the fifth and sixth embodiments, a first optical absorption film 16 that is thick at the central portion and is thin at the outer circumferential portion may be provided as in the second and third embodiments, or a sloped base 10 may be used as in the fourth embodiment.

### Seventh Embodiment

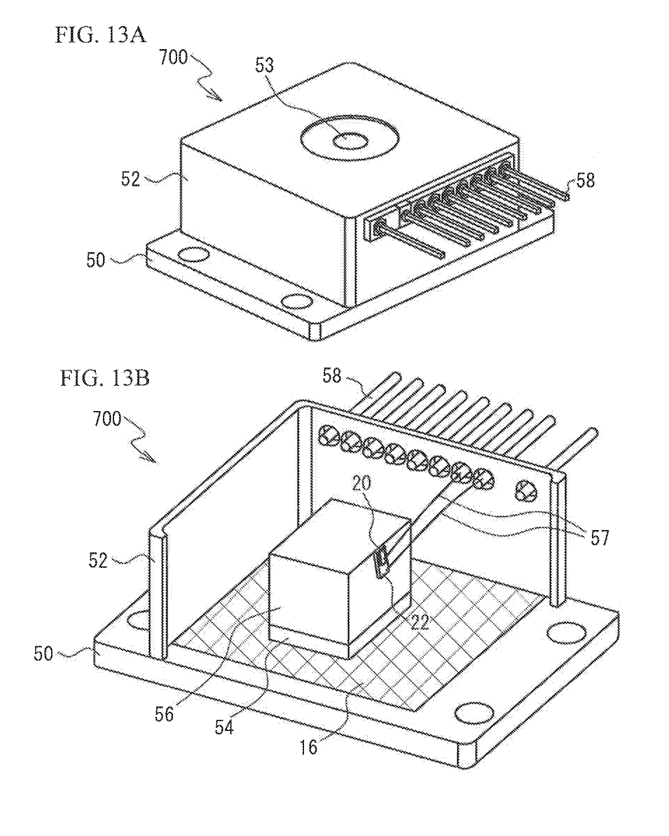

FIGS. 13A and 13B are perspective views of an optical semiconductor device 700 according to a seventh embodiment. As shown in FIGS. 13A and 13B, the optical semiconductor device 700 houses an optical semiconductor element 22 and other components in a high heat load (HHL) package.

As shown in FIGS. 13A and 13B, the optical semiconductor device 700 includes abase 50 and a cap 52. In FIG. 13B, components are seen through part of the cap 52. As shown in FIG. 13B, a first optical absorption film 16, a thermoelectric cooler (TEC) 54, a carrier 56, a sub mount 20, and the optical semiconductor element 22 are provided on the upper surface of the base 50. The first optical absorption film 16 is provided in the region inside the cap 52 on the upper surface of the base 50, and may be made of the same material with the same thickness as in the first embodiment. The TEC 54 is placed on the upper surface of the base 50, and the carrier 56 is mounted on the TEC 54. The sub mount 20 is mounted on a surface of the carrier 56, and the optical semiconductor element 22 is mounted on the sub mount 20. The TEC 54 includes a Peltier element, for example, and cools the optical semiconductor element 22.

By attaching the cap 52 to the base 50, airtight sealing is achieved. The cap 52 has an emission window 53 and wiring pins 58. As shown in FIG. 13B, one of the wiring pins 58 is electrically connected to the optical semiconductor element 22 by a bonding wire 57, and another one of the wiring pins 58 is electrically connected to the sub mount 20 by another bonding wire 57.

In the seventh embodiment, the first optical absorption film 16 absorbs the emitted light from the rear end face, and thus, the influence of reflected light can be reduced as in the first embodiment. Consequently, emitted light with excellent light collecting properties can be output from the HHL package. Of the first optical absorption film 16, the region facing the optical semiconductor element 22 may be thick while the other region is thin, as in the second and third embodiments. The upper surface of the base 50 maybe sloped so that the portion facing the optical semiconductor element 22 protrudes as in the fourth embodiment. An optical absorption film may be provided on the inner walls of the cap 52 as in the fifth and sixth embodiments.

In each of the first through seventh embodiments, the optical semiconductor element 22 may be a light emitting element other than a quantum cascade laser. To monitor outputs from the optical semiconductor element 22, a light receiving element such as a photodiode (PD) may be provided on the upper surface of the base 10 or 50. The position in which the light receiving element is to be mounted is a position facing the rear end face of the optical semiconductor element 22, for example. To reduce the influence of reflected light, an optical absorption film is preferably provided on the base region other than the portion on which the light receiving element is mounted. The portion on which the light receiving element is mounted is preferably tilted with respect to the upper surface of the base (the X-Y plane in FIG. 3). With this arrangement, the emitted light from the rear end face of the optical semiconductor element 22 is reflected in an oblique direction, and thus, is prevented from traveling toward the emission window. As for the package, any appropriate package other than the above described can-type package or the HHL package may be used, and the above described effects of each embodiment can be achieved with the package.

What is claimed is:

1. An optical semiconductor device, comprising:
a base;
an optical semiconductor element that is provided on an upper surface of the base and emits light from a front end face and a rear end face, the rear end face facing the base;
a cap that is provided on the base and has an emission window in a position facing the front end face of the optical semiconductor element, the light passing through the emission window; and
a first optical absorption film that is provided in a region on the upper surface of the base and absorbs the light, the region facing the rear end face of the optical semiconductor element.

2. The optical semiconductor device of claim 1, wherein the optical semiconductor element is a quantum cascade laser.

3. The optical semiconductor device of claim 1, wherein the first optical absorption film is one of a silicon oxide film, a silicon oxynitride film, a silicon nitride film, an alumina film, a benzocyclobutene film, and a polyimide film.

4. The optical semiconductor device of claim 1, wherein a thickness of the first optical absorption film is not smaller than 0.2 μm and not greater than 5 m.

5. The optical semiconductor device of claim 1, wherein a wavelength of the light to be emitted from the optical semiconductor element is not smaller than 7 μm and not greater than 30 μm.

6. The optical semiconductor device of claim 1, wherein a thickness of the region of the first optical absorption film facing the optical semiconductor element is greater than a thickness of a region other than the region of the first optical absorption film facing the optical semiconductor element.

7. The optical semiconductor device of claim 1, wherein the cap has a sidewall surrounding the optical semiconductor element, and
the optical semiconductor device further comprises
a second optical absorption film that is provided on the sidewall and absorbs the light.

8. The optical semiconductor device of claim 1, wherein
the cap has an upper inner wall facing the optical semiconductor element, and
the optical semiconductor device further comprises
a third optical absorption film that is provided on the upper inner wall and absorbs the light.

9. The optical semiconductor device of claim 1, further comprising
a can-type package or an HHL package.
